(19) United States
(12) Patent Application Publication
(10) Pub. No.: US 2026/0040705 A1
(43) Pub. Date: Feb. 5, 2026

(54) ENCAPSULATION METHOD FOR A-SI SENSOR PRODUCTS

(71) Applicant: dpiX, LLC, Colorado Springs, CO (US)

(72) Inventors: Geun Jo Han, Colorado Springs, CO (US); Jinhui Cho, Colorado Springs, CO (US); Jerome David Crocco, Colorado Springs, CO (US); Michael Johnson, Colorado Springs, CO (US); Seyeoul Kwon, Colorado Springs, CO (US)

(21) Appl. No.: 19/054,054

(22) Filed: Feb. 14, 2025

Related U.S. Application Data
(60) Provisional application No. 63/679,329, filed on Aug. 5, 2024.

(51) Int. Cl. H10F 39/00

(52) U.S. Cl. CPC H10F 39/804; H10F 39/016

(57) ABSTRACT

A method for forming a sensor on a substrate comprises forming an initial interlayer dielectric (ILD) layer on a top surface and a side surface of the sensor, and on a top side of the substrate; etching back the initial ILD layer to reduce an initial “bread loaf” artifact; and forming a subsequent ILD layer on the initial ILD layer. The initial ILD layer comprises a first moisture permeation seam path, and the subsequent ILD layer comprises a second moisture permeation seam path offset from the first moisture permeation seam path.

### CROSS-REFERENCE TO RELATED APPLICATIONS

This application claims the benefit of U.S. Provisional Application No. 63/679,329, filed on Aug. 5, 2024, which application is hereby incorporated herein by reference.

### TECHNICAL FIELD

The present invention relates generally to an encapsulation method for an amorphous silicon (a-Si) sensor, and, in particular embodiments, to an encapsulated a-Si sensor.

### BACKGROUND

Moisture (water vapor) penetration through seam paths, typically formed poor step coverage at high aspect ratio of step height patterns, are generated during inorganic deposition by Plasma Enhanced Chemical Vapor Deposition (PECVD) process for Inter Layer Dielectric (ILD) and passivation (PASS), leading to premature failure of a-Si sensor products as shown in FIGS. 1A and 1n FIG. 1C. The use of organic materials helps eliminate the seam path of PECVD processes and provides better step coverage of the passivation layer, meeting reliability requirements. However, employing both typical inorganic passivation process and adding organic materials for multi-passivation process (organic-inorganic) to ensure reliability, results in high-cost process because of higher organic raw material cost and additional process.

### SUMMARY

According to an embodiment, a method for forming a sensor on a substrate comprises forming an initial interlayer dielectric (ILD) layer on a top surface and a side surface of the sensor, and on a top side of the substrate; etching back the initial ILD layer to reduce an initial “bread loaf” artifact; and forming a subsequent ILD layer on the initial ILD layer.

According to an embodiment, a sensor comprises a substrate; an image sensor on the substrate; an initial ILD layer on a top surface and a side surface of the image sensor, and on a top side of the substrate; and a subsequent ILD layer on the initial ILD layer, wherein the initial ILD layer comprises a first moisture permeation seam path, and wherein the subsequent ILD layer comprises a second moisture permeation seam path offset from the first moisture permeation seam path.

According to an embodiment, a sensor comprising a substrate; an image sensor on the substrate; an initial ILD layer on a top surface and a side surface of the image sensor, and on a top side of the substrate, wherein the initial ILD layer has been etched back to reduce an initial “bread loaf” artifact; and a subsequent ILD layer on the initial ILD layer, wherein the subsequent ILD layer has been etched back to reduce a subsequent “bread loaf” artifact.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A and FIG. 1C are cross-sectional views of a sensor device according to the prior art;

FIG. 1B and FIG. 1D are cross-sectional views of a sensor device according to embodiments;

FIGS. 2A through 2F are a series of processing steps for a sensor device according to embodiments;

FIG. 3 is a cross-sectional view of an etch back process for a sensor device, according to an embodiment;

FIGS. 4A and 4B are cross-sectional views of a one-step etch back process compared to a two-step etch back process for a sensor device according to embodiments;

FIG. 5 is cross-sectional view of an etch back process for a sensor device according to an embodiment;

FIGS. 6A through 6C are plan view and cross-sectional views of an etch back process for a sensor device on a flexible substrate according to an embodiment; and

FIG. 7 is a cross-sectional view of a sensor device exhibiting moisture permeation according to the prior art.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In the following detailed description, reference is made to the accompanying drawings, which form a part hereof and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. For clarity, the same or similar elements have been designated by corresponding references in the different drawings if not stated otherwise.

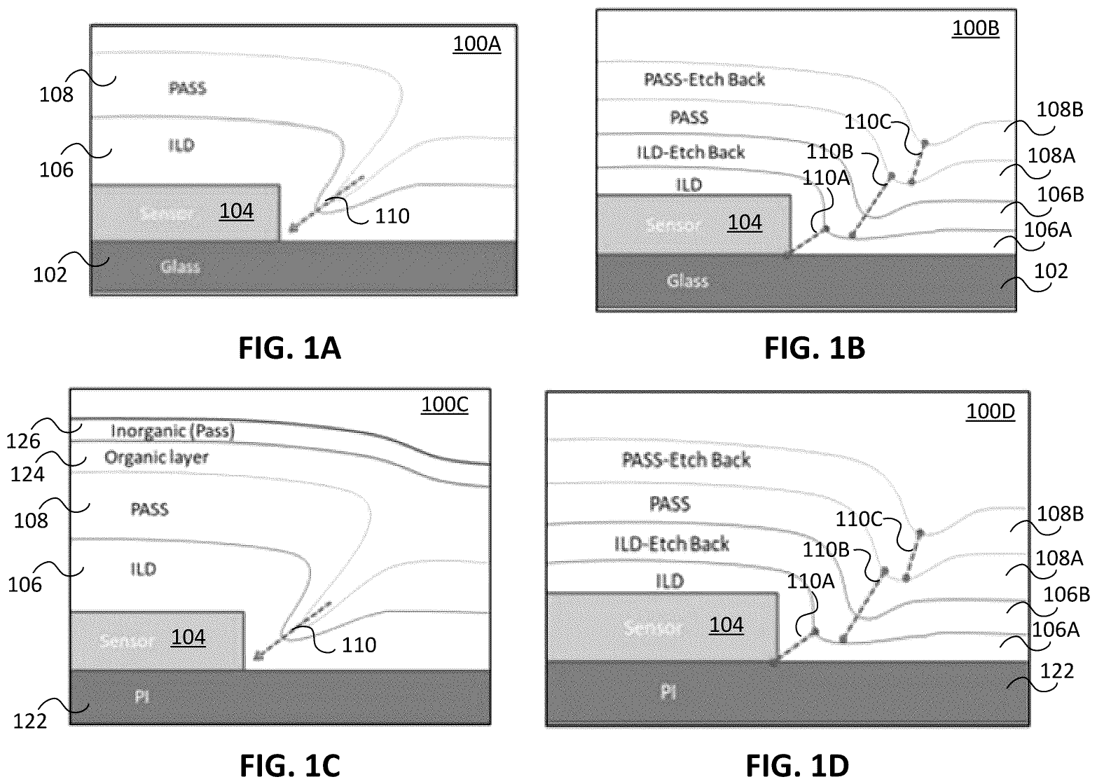

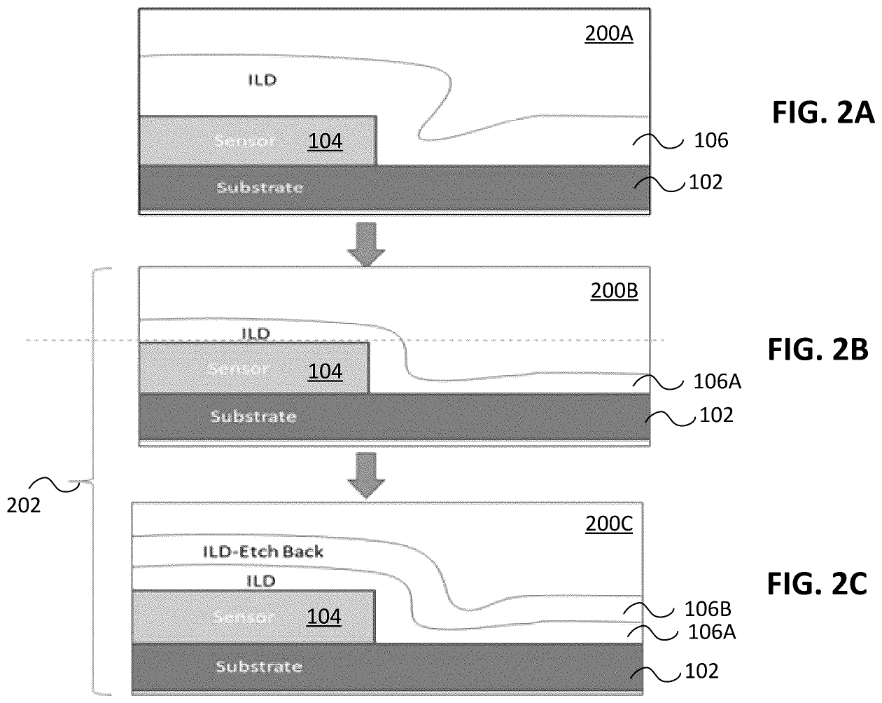

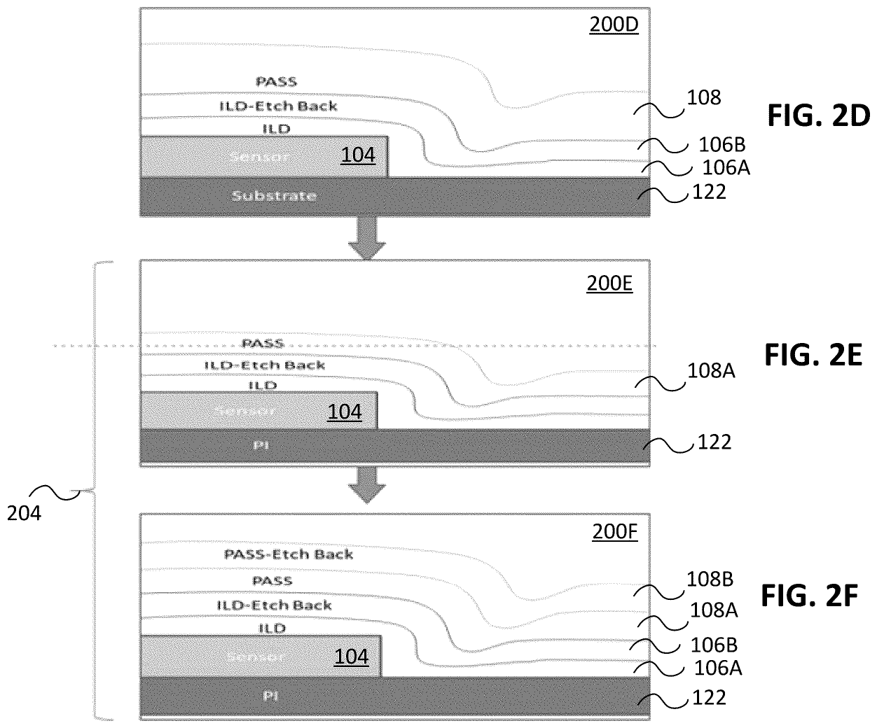

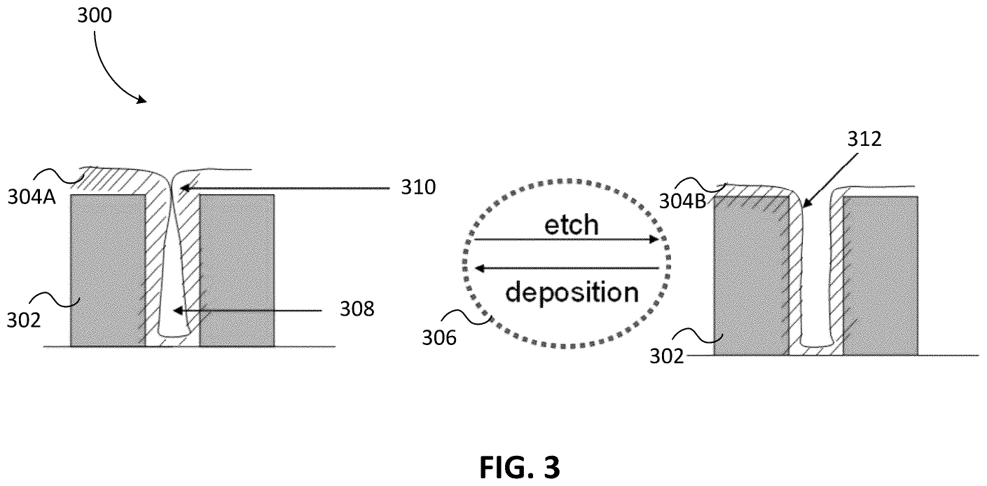

According to embodiments, a cyclic process is described below, including: inorganic deposition, dry etch, and an inorganic deposition process, called ETCH-BACK, also referred to herein as “E/B” that are employed to close the weak seam path (non-continuous seam paths) in the interlayer dielectric (ILD) and the passivation layer (PASS), which enhance the step coverage of the passivation layer by eliminating inorganic ILD bread loafing layer as shown in FIG. 1A, FIG. 1B, FIG. 2A, and FIG. 3. This cyclic process effectively meets reliability requirements and is a cost-effective in a production environment.

Embodiments described in further detail below provide the following advantages and features:
1. The ETCH-BACK process meets high reliability requirements at high temperature and humidity due to improved step coverage of inorganic layers (ILD/PASS);
2. The ETCH-BACK process is a cost-effective process as compared to present processing because of the implementation of a non-using organic coating and patterning process; and
3. While additional dry etching and deposition are required, the ETCH-BACK process is still cost effective when compared to the present ILD process.

The multiple offset moisture permeation paths improve reliability by reducing the overall failure rate due to moisture permeation to the device. The novel encapsulation technique thus provides a sensor device able to meet high reliability requirements for a-Si sensor devices and also to be used in flexible substrate-based electronics. The present encapsulation process using an inorganic layer on a-Si based photo-diode sensor is susceptible to moisture permeation because of moisture diffusion through a seam path near the high aspect ratio of step height. Therefore, typically to protect moisture permeation through a seam path at high temperature and humidity, additional organic layer or multi-layer (organic/inorganic) necessary have been employed so far. To improve the moisture-protecting property of the device, according to embodiments, an ETCH-BACK process is disclosed that offers a significant moisture barrier property due to non-continuous seam paths at a step height pattern with high aspect ratio. Non-continuous seam paths cause moisture permeation delay through a seam. Therefore, it is not necessary to use additional organic layers and multi-layers (organic/inorganic) for passivation purposes, resulting in a low-cost manufacturing process as compared to present or previous manufacturing processes. According to embodiments, the ETCH BACK process described herein are useful to many applications that require high reliability. For example, these applications include flexible substrates-based applications, flat panel display (OLED, LCD, Micro-LEDs) as well as X-ray detector sensor.

In particular, FIG. 1A shows a cross-sectional view of a prior art sensor device portion 100A having a single moisture permeation seam path 110 shown at the side edge of a sensor 104 on a glass substrate 102. The sensor 104 and glass substrate 102 are encapsulated in an ILD layer 106 and a subsequent PASS passivation layer 108. The ILD layer 106 and the subsequent PASS passivation layer 108 both exhibit significant bread load artifacts.

Another prior art sensor device portion 100C in FIG. 1C shows a sensor on a PL polyimide substrate 122 encapsulated in the ILD layer 106 and the PASS passivation layer 108. For flexible substrate applications, an additional organic layer 124 and an inorganic passivation layer 126 are used. However, the inclusion of these layers does not solve the moisture permeation issue, and there is still one dominant moisture permeation seam path 110.

FIGS. 1B and 1D show sensors manufactured according to two different embodiments. In FIG. 1B, according to a first embodiment, a sensor portion 100B is shown on a glass substrate 102 and a sensor 104 encapsulated in the ILD layer 106A, which has first moisture permeation seam path 110A. The ILD layer 106A is encapsulated with an etched-back ILD layer 106B (explained in further detail below) and a PASS passivation layer 108A, which has a second moisture permeation seam path 110B. The PASS passivation layer 108A is encapsulated in an etched-back PASS passivation layer 108B, which has a third moisture permeation seam path 110C. In the embodiment shown in FIG. 1B, the three separate moisture permeation seam paths 110A, 110B, and 110C advantageously reduce moisture permeation and increase reliability of the sensor device. While not entirely eliminating moisture permeation, the embodiment structure shown in FIG. 1B slows down and/or reduces the amount of moisture permeation.

Another embodiment shown in FIG. 1D includes the same sensor and encapsulation layers having multiple offset moisture permeation seams paths as is shown in FIG. 1B, but a flexible substrate 122 is used instead of the glass substrate 102.

FIGS. 2A through 2C, and FIGS. 2D through 2F are cross-sectional diagrams of the process flow and structure of the ETCH BACK process, according to two different embodiments.

In the first embodiment shown in FIG. 2A a sensor device portion 200A includes sensor 104 on substrate 102, which can be a glass substrate. An ILD layer 106 is used to encapsulate the sensor 104 and the substrate 102. Note that in FIG. 2A, a “bread loaf” artifact is shown in ILD layer 106. The ILD layer is formed by using PECVD deposition. In the sensor device portion 200B of FIG. 2B, the ILD layer 106A is etched back using a dry etching technique, which removes the “bread loaf” artifact as shown. In the sensor device portion 200C of FIG. 2C, a subsequent ILD layer 106B is deposited on the etched-back ILD layer 106A using PECVD deposition. The subsequent ILD layer 106B is then also etched-back to remove subsequent “bread loaf” artifacts. The processing technique can be repeated in multiple cycles, that is step coverage and etching back, which created multiple offset moisture permeation seam paths. FIGS. 2B and 2C illustrate the etch back steps 202 of the process flow.

In the second embodiment of FIGS. 2D through 2F a similar processing flow for creating the multiple offset seam paths using a PASS passivation layer is shown. The sensor device portion 200D of FIG. 2D also shows sensor 104 on a flexible substrate 122 encapsulated with at ILD layer 106A and an etched-back ILD layer 106B. A PASS passivation layer 108 is then deposited on the etched-back ILD layer 106B using PECVD deposition. The PASS passivation layer 108 may also include a “bread loaf” artifact. In the sensor device portion 200E of FIG. 2E, the PASS passivation layer 108A is etched back using a dry etching technique. The dry etching technique removes any “bread loaf” artifacts in the passivation layer 108A. In the sensor device portion 200F of FIG. 2F, another PASS passivation layer 108B is deposited and also etched back. As described above with respect to the first embodiment of FIGS. 2A through 2C, the passivation layer processing can be repeated in multiple cycles, namely, step coverage and etching back. Together with the ILD layers, multiple offset moisture permeation seams paths are formed resulting in greater reliability and improved performance of the sensor. FIGS. 2E and 2F illustrate the etch back steps 204 of the process flow.

In summary, moisture (water vapor) penetration through seam paths and poorly formed step coverage at high aspect ratio of step height patterns are generated during inorganic deposition by Plasma Enhanced Chemical Vapor Deposition (PECVD) process for Inter Layer Deposition (ILD) and passivation (PASS), leading to premature failure of a-Si sensor products as shown for example in FIG. 1A. FIG. 1B shows in schematic form one approach to solve the moisture permeation issue, according to an embodiment. The use of organic materials helps eliminate the seam path of PECVD processes and provides better step coverage of the passivation layer, meeting reliability requirements. However, employing both typical inorganic passivation process and adding organic materials for multi-passivation process (organic-inorganic) to ensure reliability, results in high-cost process because of higher organic raw material cost and additional process.

According to embodiments, a cyclic process described herein includes: inorganic deposition, dry etch, and inorganic deposition process, called ETCH-BACK, which is employed to advantageously close the weak seam path (non-continuous seam paths) in the ILD and PASS layers, which enhances the step coverage of the passivation layer by eliminating inorganic ILD bread loafing layer as shown in FIG. 1B and FIG. 1D. Testing has confirmed that embodiments of the cyclic process described herein effectively meets reliability requirements while remaining a cost-effective manufacturing process.

FIG. 3 shows a schematic of one step 300 of the ETCH BACK process to improve step coverage of the inorganic ILD and PASS layers. Step 300 shows a step feature 302 and a representative coverage layer 304A, which could be an ILD or PASS passivation layer. The bread loaf 310 can be formed at a high aspect ratio of step height pattern during PECVD process, showing poor step coverage 308. To enhance step coverage (to remove bread loaf), a dry etching process after PECVD process is performed. After the dry etching process, coverage layer 304B is shown without any bread loaf artifact, particularly shown at location 312. The deposition and etching steps 306 can be repeated for multiple cycles using the ILD and/or PASS layers in order to generate multiple offset seam paths to increase reliability of the sensor device.

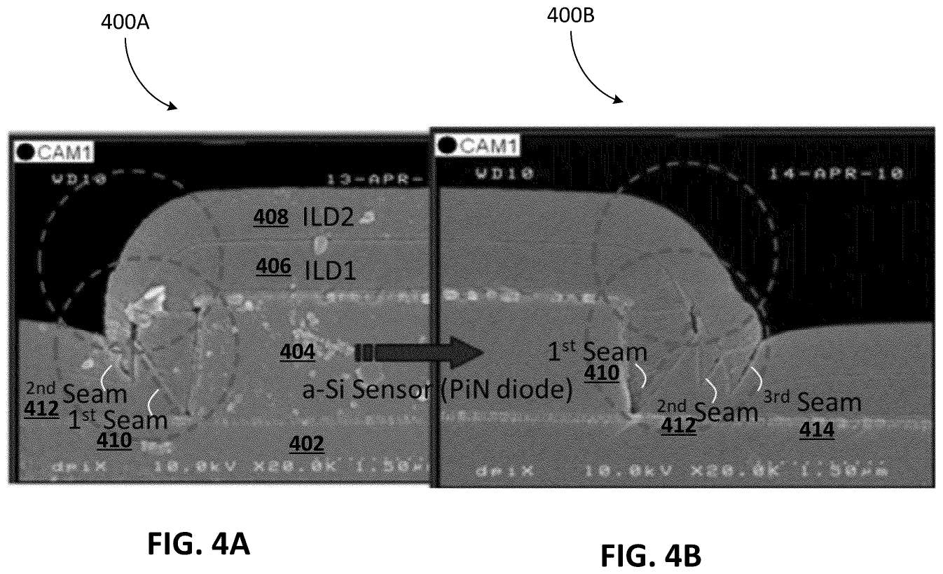

FIG. 4A shows a cross-sectional SEM image after one application and FIG. 4B shows two applications of the ETCH BACK process, respectively. A first sensor device portion 400A and a second sensor device portion 400B are respectively shown. The one-time application of the ETCH BACK process provides two non-continuous seam paths (1^{st} seam 410 and 2^{nd} seam 412) and the two-time application of the ETCH BACK process provides three non-continuous seam paths (1^{st} seam 410, 2^{nd} seam 412, and 3^{rd} seam 414). The use of “non-continuous seams” means that moisture is barely permeates into an a-Si sensor through the offset seams from outside of the sensor. The use of the non-continuous seams produces a longer defect path with multiple interfaces between the various multi-inorganic layers (ILD layers). Also depicted in FIG. 4A and FIG. 4B is a substrate 402, a sensor 404, a first ILD layer 406, and a second ILD layer 408.

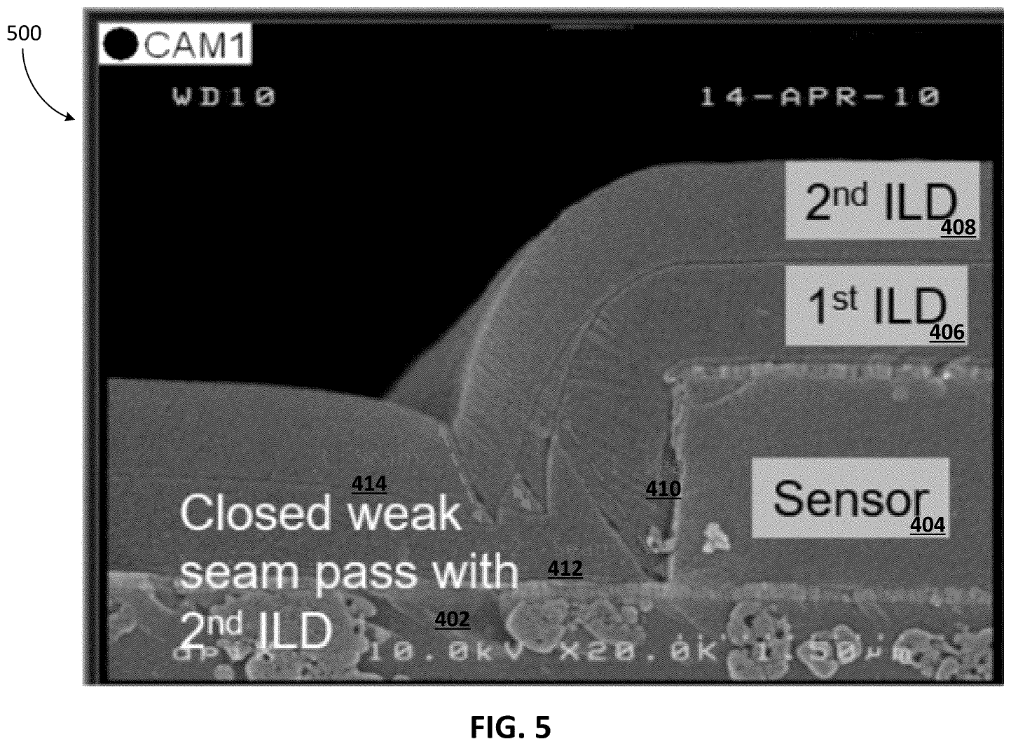

FIG. 5 shows another example of the cross-section SEM image after two applications of the ETCH BACK process. A sensor device portion 500 is depicted showing the non-continuous seam paths ore clearly. The defect line along the red dot line (1^{st} seam 410) is the initial seam path that was formed 1st ILD process by PECVD. The first seam 410 (in a first ILD layer 406) is terminated by following a dry etch process and deposition. This means that moisture from outside the sensor device will be substantially prevented from diffusing into sensor 404 through 1st seam 410. The second seam (2^{nd} seam 412) is terminated by the 2^{nd} ILD layer 208. Three separate discontinuous or offset moisture permeation seam paths are shown in FIG. 5 (1^{st} seam 410, 2^{nd} seam 412, and 3^{rd} seam 414).

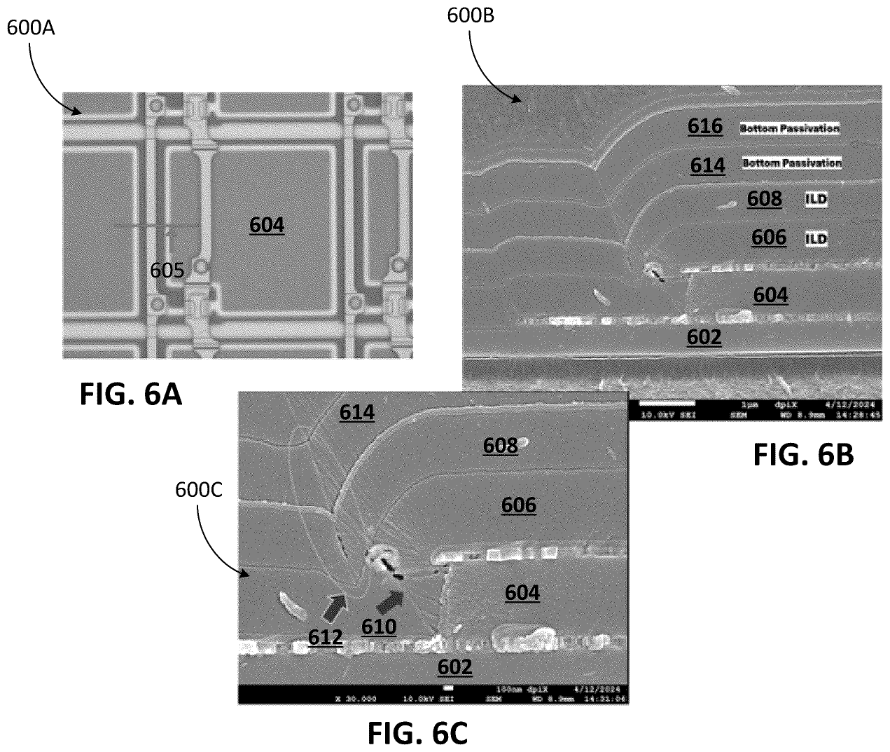

FIGS. 6A, 6B, and 6C shows an example embodiment sensor device using the ETCH BACK process for a flexible substrate-based application. FIG. 6A shows a plan view of a sensor device including a sensor 604, and line 605 indicating the location of the cross-sectional views shown in FIGS. 6B and 6C. FIG. 6B shows a cross-sectional view of a sensor device having an etched back ILD layer 606, and a subsequent ILD layer 608, an etched back PASS passivation layer 614, and a subsequent PASS passivation layer 616. Also depicted are the substrate 602 and sensor 604. FIG. 6C shows another cross-section view of the sensor device including the component layers shown in FIG. 6B, but also includes a clear view of the first seam path 610 and the non-continuous second seam path 612. In other embodiments, any inorganic ILD or PASS layers that comprise a silicon oxide (SiO₂), silicon nitride (SiNₓ), and/or silicon oxynitride (SiON) can be used in the ETCH BACK process described herein.

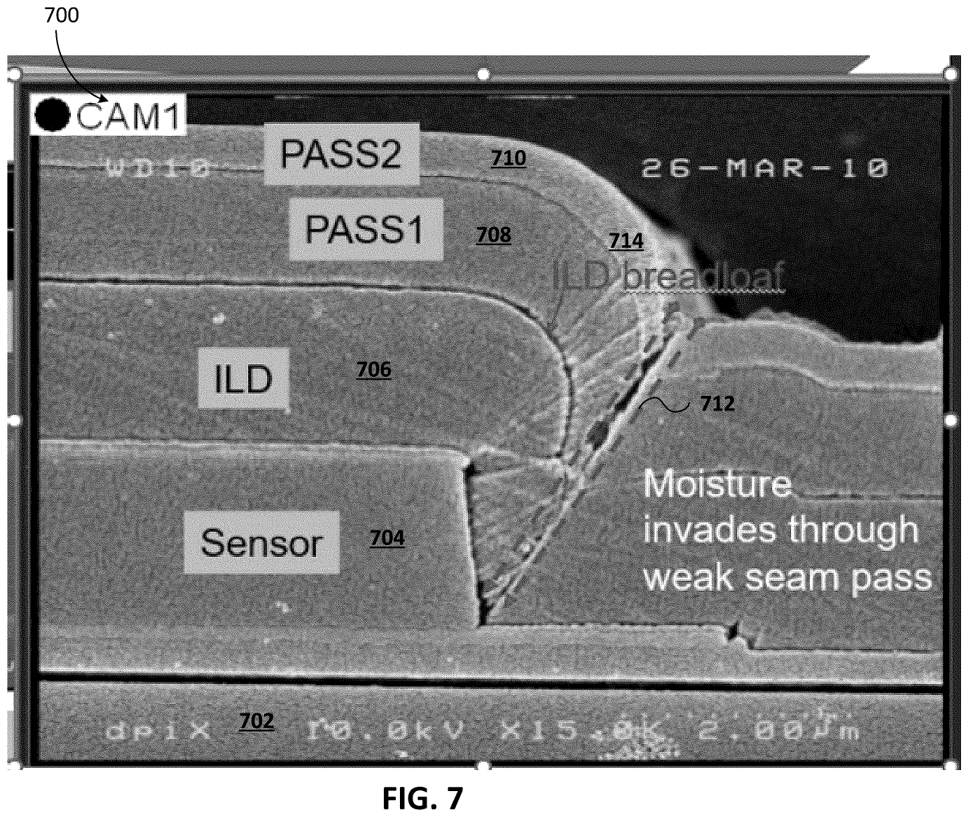

FIG. 7 shows the cross-section SEM image of current technology in which moisture can be permeated into sensor diode through a seam formed during ILD process, despite the use of an ILD layer and two separate PASS layers. FIG. 7 shows a substrate 702, a sensor 704, ILD layer 706, passivation layer 708, and passivation layer 710. ILD layer 706 can be seen to include a bread loaf artifact 714. The sensor device portion shown in FIG. 7 includes a single seam path 712 that allows moisture intrusion and a loss of reliability in the sensor device.

In summary, to improve the reliability of an a-Si sensor due to moisture permeation, an ETCH BACK process, including inorganic deposition-dry etching-inorganic deposition steps, is described below. Embodiments advantageously provide sensor devices of high reliability and cost-effectiveness when compared to prior solutions.

Examples of TFT image sensors that will benefit from incorporating the ETCH BACK process described herein include U.S. Pat. No. 10,872,928 entitled “Method of Manufacturing an Enhanced High Performance Image Sensor,” U.S. Pat. No. 10,026,863 entitled “Method of Manufacturing a Sensor Array,” and U.S. Pat. No. 9,786,856 entitled “Method of Manufacturing an Image Sensor Device,” which are all hereby incorporated by reference. Other TFT image sensor devices will also benefit from incorporating the ETCH BACK process described herein to prevent moisture permeation into the device in order to improve reliability.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for forming a sensor on a substrate, the method comprising:
forming an initial interlayer dielectric (ILD) layer on a top surface and a side surface of the sensor, and on a top side of the substrate;
etching back the initial ILD layer to reduce an initial “bread loaf” artifact; and
forming a subsequent ILD layer on the initial ILD layer.

2. The method of claim 1, wherein the initial ILD layer comprises a first moisture permeation seam path, and wherein the subsequent ILD layer comprises a second moisture permeation seam path offset from the first moisture permeation seam path.

3. The method of claim 1, further comprising:
etching back the subsequent ILD layer to reduce a subsequent “bread loaf” artifact; and
forming an additional subsequent ILD on the subsequent ILD layer.

4. The method of claim 3, further comprising performing one or more cycles of etching back and forming additional subsequent ILD layers.

5. The method of claim 4, wherein additional subsequent layers comprise additional offset moisture permeation seam paths.

6. The method of claim 1, wherein forming each of the initial ILD layer and the subsequent ILD layer comprises performing a Plasma Enhanced Chemical Vapor Deposition (PECVD) process.

7. The method of claim 1, wherein etching back the initial ILD layer comprises performing a dry etch.

8. The method of claim 1, wherein the sensor comprises an image sensor.

9. The method of claim 8, wherein the image sensor comprises an amorphous-silicon (a-SI) thin-film transistor (TFT) image sensor.

10. The method of claim 1, wherein the substrate comprises a glass substrate or a flexible substrate.

11. A sensor comprising:
a substrate;
an image sensor on the substrate;
an initial ILD layer on a top surface and a side surface of the image sensor, and on a top side of the substrate; and
a subsequent ILD layer on the initial ILD layer, wherein the initial ILD layer comprises a first moisture permeation seam path, and wherein the subsequent ILD layer comprises a second moisture permeation seam path offset from the first moisture permeation seam path.

12. The sensor of claim 11, further comprising:
one or more additional subsequent ILD layers on the subsequent ILD layer, wherein each one or more additional subsequent ILD layer comprises a subsequent moisture permeation seam path offset from the first moisture permeation seam path, the second moisture permeation seam path, and each subsequent moisture permeation seam path.

13. The sensor of claim 12, further comprising a passivation layer on the one or more subsequent ILD layers.

14. The sensor of claim 11, wherein the image sensor comprises an a-SI TFT image sensor.

15. The sensor of claim 11, wherein the substrate comprises a glass substrate or a flexible substrate.

16. A sensor comprising:
a substrate;
an image sensor on the substrate;
an initial ILD layer on a top surface and a side surface of the image sensor, and on a top side of the substrate, wherein the initial ILD layer has been etched back to reduce an initial “bread loaf” artifact; and
a subsequent ILD layer on the initial ILD layer, wherein the subsequent ILD layer has been etched back to reduce a subsequent “bread loaf” artifact.

17. The sensor of claim 16, further comprising:
one or more additional subsequent ILD layers on the subsequent ILD layer, wherein each one or more subsequent ILD layer has been etched back to reduce additional subsequent “bread loaf” artifacts.

18. The sensor of claim 17, further comprising a passivation layer on the one or more additional subsequent ILD layers.

19. The sensor of claim 16, wherein the image sensor comprises an a-SI TFT image sensor.

20. The sensor of claim 16, wherein the substrate comprises a glass substrate or a flexible substrate.
